(19) United States
(12) Patent Application Publication
(10) Pub. No.: US 2015/0346312 A1
(43) Pub. Date: Dec. 3, 2015

(54) METHOD FOR SETTING UP A CURRENT SENSOR

(71) Applicant: CONTINENTAL TEVES AG & CO. OHG, Frankfurt (DE)

(72) Inventors: Jörg Eckrich, Wiesbaden (DE); Wolfgang Jöckel, Gersfeld (DE); Klaus Rink, Rodenbach (DE); Torsten Martin, Steinbach/Taunus (DE); Martin Haverkamp, Frankfurt (DE); Jens Herchenröder, Brachttal-Udenhain (DE)

(21) Appl. No.: 14/653,466

(22) PCT Filed: Nov. 22, 2013
(86) PCT No.: PCT/EP2013/074522

§ 371 Date: Jun. 18, 2015

(30) Foreign Application Priority Data
Dec. 20, 2012 (DE) 10 2012 224 112.4

(51) Int. Cl. G01R 35/00; G01R 19/00

(52) U.S. Cl. CPC G01R 35/007; G01R 19/0092

(57) ABSTRACT

A method for setting up a current sensor having an internal resistance which is dependent on the current which is to be measured, wherein the internal resistance is set to a setpoint voltage drop as part of a regulation of an actual voltage drop across the current sensor, including calibration or checking the plausibility of operation of the current sensor based on a characteristic curve, in which the current which is to be measured is compared to a variable which is dependent on the internal resistance or to the internal resistance.

### CROSS REFERENCE TO RELATED APPLICATIONS

This application is the U.S. National Phase Application of PCT/EP2013/074522, filed Nov. 22, 2013, which claims priority to German Patent Application No. 10 2012 224 112.4, filed Dec. 20, 2012, the contents of such applications being incorporated by reference herein.

### FIELD OF THE INVENTION

The invention relates to a method for setting up a current sensor having an internal resistance which is dependent on the current to be measured, to a control device for performing the method and to a current sensor having the control device.

### BACKGROUND OF THE INVENTION

In order to perform measurements of an electric current flowing between an electrical energy source and an electrical consumer in a motor vehicle, a current sensor can be connected in series between the electrical energy source and the electrical consumer. A current sensor of this type is known, for example, from DE 10 2011 078 548 A1, which is incorporated by reference.

### SUMMARY OF THE INVENTION

The problem addressed by the present invention is to improve current measurement.

According to an aspect of the invention, a method for testing a current sensor having an internal resistance which is dependent on the current to be measured, wherein the internal resistance is set to a setpoint voltage drop as part of regulation of an actual voltage drop across the current sensor, comprises the step of calibrating or performing a plausibility check on an operation of the current sensor on the basis of a characteristic curve in which the current to be measured is compared to a variable dependent on the internal resistance or is compared to the internal resistance.

While it is possible in principle to check the functionality of the current sensor with the step of performing a plausibility check on the current sensor, the functionality of the current sensor can then be fundamentally established with the step of calibrating.

The specified method is based on the discovery that a common current-voltage characteristic curve of the current sensor mentioned at the outset, which characteristic curve incidentally has a broken rational profile, cannot be directly plotted in order to determine accurate functionality by performing a plausibility check and/or to ensure accurate functionality by calibration. However, the controller of the current sensor of the specified method always reacts such that, when a value of the current to be measured is changing, the value of the internal resistance of the current sensor also changes in order to set up the actual voltage drop across the current sensor according to the setpoint voltage drop across the current sensor. Proceeding from this discovery, it is recognized as part of the specified method that the current sensor can be characterized on the basis of a characteristic curve in which the changing internal resistance or a control variable influencing the changing internal resistance is plotted via the current to be measured. Said characteristic curve is used in the specified method in order to ensure the accurate functionality of the specified current sensor as part of calibrating or performing a plausibility check.

In a development of the specified method, the actual voltage drop across the current sensor is lower during setting-up of the current sensor than during normal operation of the current sensor. This development is based on the discovery that what is decisive for the correct functionality of the current sensor is not whether the current sensor can form a corresponding changing internal resistance or a corresponding control variable influencing said internal resistance for all expected values of the current to be measured, but whether a shape of the plotted characteristic curve corresponds to an expected shape. The shape of the characteristic curves is dependent in a particular manner on the setpoint voltage to be set owing to the control circuit of the current sensor from the specified method. That is to say that, if the shape of the characteristic curve in the test case corresponds to an expected shape, it can be concluded that the current sensor also functions during normal operation. In the same way, the current sensor can be calibrated with a setpoint shape on the basis of a characteristic curve.

What is particularly expedient in the development of the specified method is that the calibration or the performing of a plausibility check on the current sensor can be performed on the basis of a current which is significantly lower than the currents to be measured during normal operation of the current sensor. In this way, the power consumption of the current sensor during calibration and performing of a plausibility check and hence the power loss and the associated self-heating of the current sensor can be kept small.

In a particular development of the specified method, the actual voltage drop for testing the current sensor is less than 50%, preferably less than 20%, particularly preferably less than 10% of the value of the actual voltage drop during normal operation of the current sensor.

In an additional development of the specified method, the actual voltage drop is selected during setting-up of the current sensor on the basis of a maximum permissible electric power consumption of the current sensor during the test. In this way, the power loss at the current sensor and hence the heating thereof during setting-up thereof can be kept limited.

In another development of the specified method, the internal resistance of the current sensor is composed of at least two parallel-connected partial shunts which are controllable as part of the regulation, wherein at least one controllable partial shunt is removed from the parallel circuit for the purpose of calibrating or performing a plausibility check on the current sensor. In this way, the internal resistance of the current sensor can be reduced, as a result of which the actual voltage drop across the current sensor during testing of the current sensor is lower than during normal operation of the current sensor for the same current through the current sensor.

Particularly preferably, at most one controllable partial shunt remains in the parallel circuit for the purpose of calibrating or performing a plausibility check on the current sensor, with the result that the actual voltage drop across the current sensor during setting-up and hence the power consumption thereof is minimal.

In an alternative or additional development, the specified method comprises the step of determining a value for the setpoint voltage drop for the purpose of calibrating or performing a plausibility check on the current sensor on the basis of the characteristic curve. In this way, the actual voltage drop across the current sensor can be influenced by the controller. Since the voltage drop across the current sensor together with the current through the current sensor can determine the internal resistance of said current sensor, the actual voltage drop across the current sensor during setting-up of the current sensor can be influenced and therefore configured to be lower than during normal operation of the current sensor.

In addition, the determined setpoint voltage drop for the purpose of calibrating or performing a plausibility check on the current sensor on the basis of the characteristic curve is particularly preferably selected to be lower than a setpoint voltage drop during normal operation of the current sensor.

According to another aspect of the invention, a control device is set up to perform a method as claimed in any of the preceding claims.

In a development of the specified control device, the specified device has a memory and a processor. In this case, the specified method is stored in the memory in the form of a computer program and the processor is provided to perform the method when the computer program is loaded from the memory into the processor.

According to another aspect of the invention, a computer program comprises program code means in order to perform all of the steps of one of the specified methods when the computer program is executed on a computer or one of the specified devices.

According to another aspect of the invention, a computer program product comprises program code which is stored on a computer-readable data carrier and which performs one of the specified methods when said program code is executed on a data processing device.

### BRIEF DESCRIPTION OF THE DRAWINGS

The above-described properties, features and advantages of the present invention and the manner in which these are achieved will become more clearly and unambiguously understandable in connection with the following description of the exemplary embodiments which are explained in more detail with reference to the drawings, in which:

FIG. 1 shows a schematic view of a vehicle battery circuit which is connected to a vehicle battery pole and has two current sensors;

FIG. 2 shows a schematic view of a control circuit for controlling the current sensor from FIGS. 1; and

FIG. 3 shows characteristic curves in which the currents flowing through the current sensor are compared to their control voltages on the basis of a voltage drop across the current sensor.

### DETAILED DESCRIPTION OF THE INVENTION

In the figures, identical technical elements are provided with identical reference signs and are described only once.

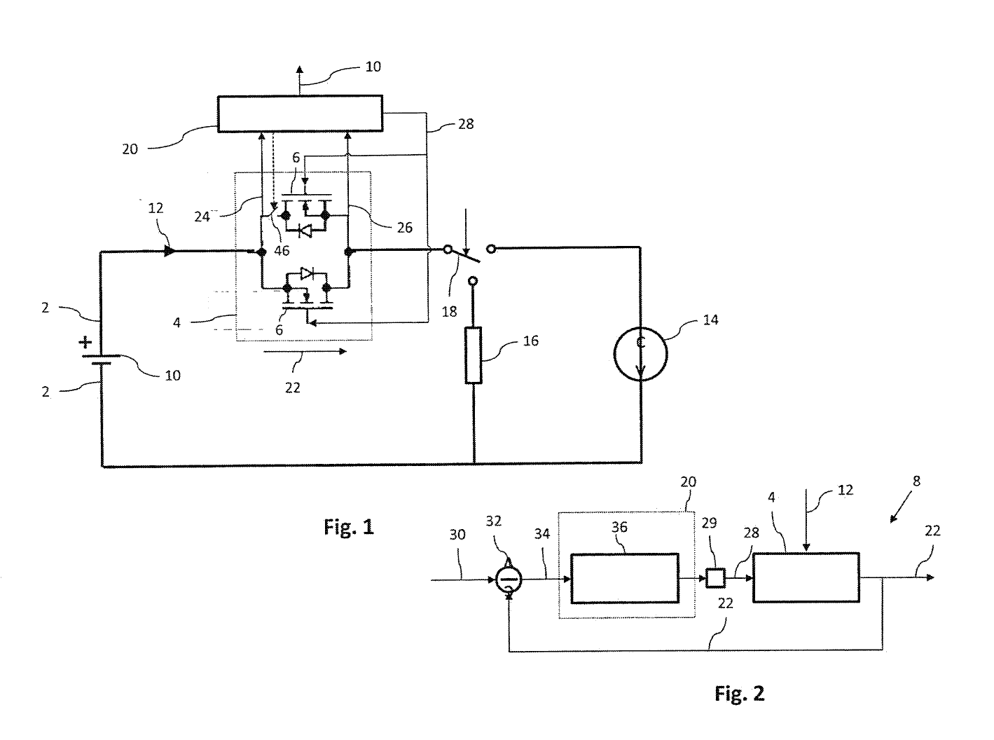

Reference is made to FIGS. 1 and 2 which correspondingly show a schematic view of a vehicle battery circuit 4 with two partial shunts 6 which is connected to a vehicle battery pole 2 and is designed as a current sensor and a schematic view of a control circuit 8 for controlling the partial shunts 6 from FIG. 1.

The vehicle battery pole 2 is one of two vehicle battery poles 2 of a vehicle battery 10. Via the vehicle battery pole 2 and the vehicle battery circuit 4 which is connected to one of the vehicle battery poles 2, an electric current 12 can be consumed by an electrical energy source 14, for example a socket, or provided to an electrical consumer 16, for example a drive motor of a vehicle which is not illustrated in more detail.

In order to avoid the electrical consumer 16 being directly connected to the electrical energy source 14, the electrical energy source 14 and the electrical consumer 16 can additionally be electrically isolated from one another by means of a changeover switch 18, with the result that, depending on the position of the changeover switch 18, either the electrical energy source 14 or the electrical consumer 16 is connected to the vehicle battery 10.

The vehicle battery circuit 4 with the partial shunts 6 can be constructed in accordance with the active shunt disclosed in DE 10 2011 078 548 A1. For this purpose, each partial shunt 6 in the present embodiment has a field-effect transistor which is not referenced in more detail and a freewheeling diode which is not referenced in more detail and is interconnected in the forward direction from source to drain. Both partial shunts 6 are interconnected in parallel with one another.

FIG. 1 also shows an evaluation circuit 20. The evaluation circuit 20 may be designed as part of the vehicle battery circuit 4 or as a separate circuit. In the present embodiment, by way of example, the vehicle battery circuit 4 is designed to be separate from the evaluation circuit 20.

In the present embodiment, the evaluation circuit 20 controls the field-effect transistors of the partial shunts 6 such that a voltage drop 22 across the partial shunts 6 is kept at a particular setpoint value. For this purpose, the evaluation circuit 20 receives a first electric potential 24 which is tapped from the vehicle battery 10 seen from upstream of the partial shunt 6 and a second electric potential 26 which is tapped from the vehicle battery 10 seen from downstream of the partial shunt 6. The voltage drop 22 is determined from the difference between the first electric potential 24 and the second electric potential 26.

By driving the gates of the field-effect transistors of the partial shunt 6 with a control signal 28, the voltage drop 22 is kept at the setpoint value 30 via the control circuit 8 shown in FIG. 2. As shown in DE 10 2011 078 548 A1, the control signal 28 is dependent on the electric current 12 to be measured. Therefore, if said dependency is stored in the evaluation circuit 20, the electric current 12 can be derived directly from the control signal 28. In the present embodiment, the partial shunts 6 and hence the vehicle battery circuit 4 are interconnected such that they can measure the current 12 out of the vehicle battery 10. In order to be able to measure a current 12 into the vehicle battery 10, further partial shunts which are interconnected back-to-back in parallel with the shown partial shunt 6 from FIG. 1 would be necessary. The measurement principle of the current 12 flowing into the battery would then correspond to the previously described measurement principle.

In the present embodiment, the control circuit 8 comprises the vehicle battery circuit 4 as control path, which vehicle battery circuit is driven by the control signals 28 in the manner described previously, with the result that the voltage drop 22 can be tapped via the partial shunts 6 of the vehicle battery circuit 4. Said voltage drop 22 is compared at a difference member 32 to the setpoint value 30 by subtraction, wherein a control difference 34 results which is output to a controller 36 which is known to a person skilled in the art and arranged in the evaluation circuit 20. The controller 36 then in turn generates the control signals 28 in order to keep the voltage drop 22 at the setpoint value 30.

Further details relating to the partial shunts 6 or to the evaluation circuit 20 thereof can be gathered from DE 10 2011 078 548 A1, which has already been mentioned.

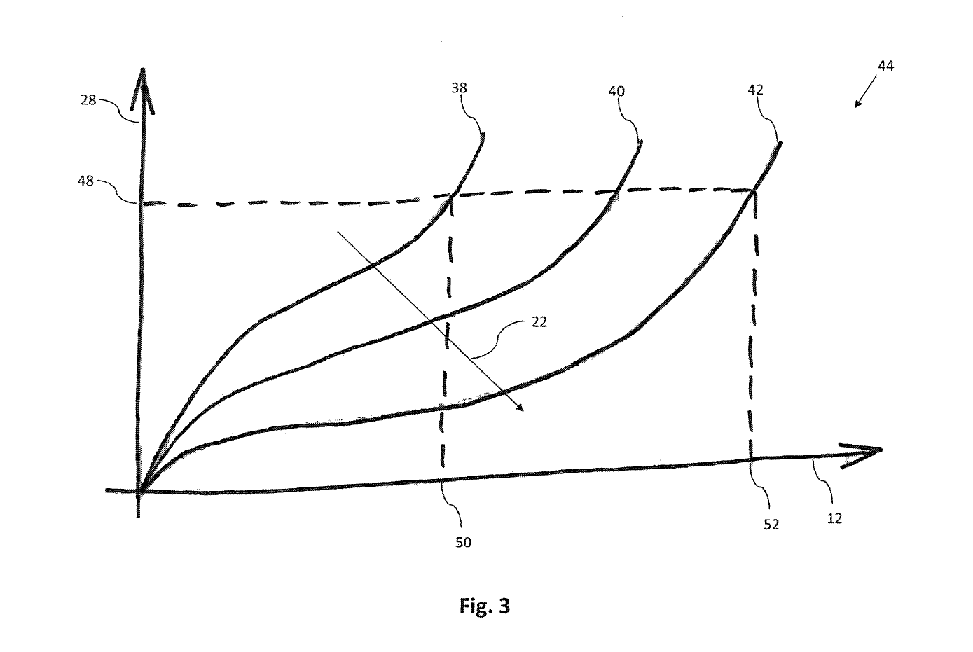

In the present embodiment, the vehicle battery circuit 4 which is designed as current sensor should be tested for the accurate functionality thereof and/or calibrated for the functionality thereof. In the present embodiment, this is performed on the basis of one of the characteristic curves 38, 40, 42 shown in FIG. 3, which characteristic curves are plotted on a graph 44 in which the control signal 28 is plotted over the current 12 to be measured.

The embodiment is based on the discovery that the control signal 28 adjusts the internal resistance of the field-effect transistors in the partial shunts 6 since the greater the current 12 to be measured, the lower the internal resistance of the field-effect transistors in the partial shunts 6 has to be in order that the voltage drop 22 remains constant. As is known, the internal resistance of a field-effect transistor falls with an increasing drive voltage. The higher the value of the control signal 28, the lower the internal resistance of the partial shunts 6 thus is.

The previously mentioned principle is clearly visible from the characteristic curves 38, 40, 42 shown in FIG. 3, according to which the control circuit reduces the internal resistance of the partial shunts 6 in the case of an increasing current 12 to be measured because it drives said partial shunts with a correspondingly higher control signal 28. The individual characteristic curves 38, 40, 42 depend in this case on the voltage drop 22 to be adjusted. The greater this is selected to be, the greater the current 12 measurable using the corresponding characteristic curve 38, 40, 42 is.

While comparatively high currents flow during normal operation of the vehicle battery circuit 4, the embodiment uses the previously mentioned finding for the testing and/or calibrating of the vehicle battery circuit 4 and deliberately selects a characteristic curve which is as steep as possible of the three characteristic curves in order to perform the testing and/or calibrating with a current 12 which is a low as possible and a voltage drop 22 which is as low as possible. In this way, the power consumption of the vehicle battery circuit 4 can be kept low.

For this purpose, firstly, the evaluation circuit 20 can remove one of the two partial shunts 6 from the parallel circuit of the vehicle battery circuit 4 via a switch 46 and thus increase its internal resistance. In this way, the voltage drop would fall in the case of an identical current 12, with the result that the vehicle battery circuit 4 would slip onto a characteristic curve of the characteristic curves 38, 40, 42 which is shown more to the left when regarding the image plane of FIG. 3.

Particularly preferably, the left-most characteristic curve 38 of the characteristic curves 38, 40, 42 is selected.

Alternatively or in addition, the setpoint value 30 for the voltage drop 22 could also be selected to be lower, which would lead to the same result.

A maximum value 48 of the control signal 28 could in this way be achieved in the test or calibration case with a lower current value 50 of the current 12 to be measured than a maximum current value 52 which can be measured during normal operation of the vehicle battery circuit 4.

1. A method for setting up a current sensor having an internal resistance which is dependent on the current to be measured, wherein the internal resistance is set to a setpoint voltage drop as part of regulation of an actual voltage drop across the current sensor, said method comprising calibrating or performing a plausibility check on an operation of the current sensor on the basis of a characteristic curve in which the current to be measured is compared to a variable dependent on the internal resistance or is compared to the internal resistance.

2. The method as claimed in claim 1, wherein the actual voltage drop across the current sensor is lower during setting-up of the current sensor than during normal operation of the current sensor.

3. The method as claimed in claim 2, wherein the actual voltage drop for testing the current sensor is less than 50% of the value of the actual voltage drop during normal operation of the current sensor.

4. The method as claimed in claim 2, wherein the actual voltage drop is selected during setting-up of the current sensor on the basis of a maximum permissible electric power consumption of the current sensor during the test.

5. The method as claimed in claim 1, wherein the internal resistance of the current sensor is composed of at least two parallel-connected partial shunts which are controllable as part of the regulation and one controllable partial shunt is removed from the parallel circuit for the purpose of calibrating or performing a plausibility check on the current sensor.

6. The method as claimed in claim 5, wherein at most one controllable partial shunt remains in the parallel circuit for the purpose of calibrating or performing a plausibility check on the current sensor on the basis of the characteristic curve.

7. The method as claimed in claim 1, comprising determining a value for the setpoint voltage drop for the purpose of calibrating or performing a plausibility check on the current sensor on the basis of the characteristic curve.

8. The method as claimed in claim 7, wherein the determined setpoint voltage drop for the purpose of calibrating or performing a plausibility check on the current sensor on the basis of the characteristic curve is lower than a setpoint voltage drop during normal operation of the current sensor.

9. A control device which is set up to perform a method for setting up a current sensor having an internal resistance which is dependent on the current to be measured, wherein the internal resistance is set to a setpoint voltage drop as part of regulation of an actual voltage drop across the current sensor, said method comprising calibrating or performing a plausibility check on an operation of the current sensor on the basis of a characteristic curve in which the current to be measured is compared to a variable dependent on the internal resistance or is compared to the internal resistance.

10. A current sensor for detecting a current from or in a vehicle battery, comprising a control device as claimed in claim 9.

11. The method as claimed in claim 2, wherein the actual voltage drop for testing the current sensor is less than 20% of the value of the actual voltage drop during normal operation of the current sensor.

12. The method as claimed in claim 2, wherein the actual voltage drop for testing the current sensor is less than 10% of the value of the actual voltage drop during normal operation of the current sensor.

13. The method as claimed in claim 3, wherein the actual voltage drop is selected during setting-up of the current sensor on the basis of a maximum permissible electric power consumption of the current sensor during the test.
